(19) United States
(12) Patent Application Publication
(10) Pub. No.: US 2005/0141276 A1
(43) Pub. Date: Jun. 30, 2005

(54) Semiconductor memory device and production method therefor

(75) Inventors: Noboru Takeuchi, Fukuyama-shi (JP); Satoru Yamagata, Fukuyama-shi (JP); Shinichi Sato, Fukuyama-shi (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 11/019,474

(22) Filed: Dec. 23, 2004

(30) Foreign Application Priority Data
Dec. 26, 2003 (JP) 2003-434423

(51) Int. Cl. G11C 16/04

(52) U.S. Cl. 365/185.18

(57) ABSTRACT

A semiconductor memory device including: a semiconductor substrate; a plurality of memory cells arranged in a matrix having columns and rows on the semiconductor substrate and each including a source, a drain and a control gate; a plurality of insulative device isolation layers positioned in a surface portion of the substrate as extending in a column direction for isolating the memory cells arranged in each row of the matrix; a plurality of word lines positioned on the substrate as extending in a row direction and each constituted by the control gates of the memory cells of the each row which are connected in series; the source and the drain of each of the memory cells of the each row being positioned in the surface portion of the substrate on opposite sides of a corresponding one of the word lines between an adjacent pair of insulative device isolation layers; and a common source line positioned on the substrate between an adjacent pair of word lines with the intervention of side wall films positioned on side walls of the word lines as extending across the insulative device isolation layers and connecting the sources of the memory cells of the each row in series.

### CROSS-REFERENCE TO RELATED APPLICATION

This application is related to Japanese application No. 2003-434423 filed on Dec. 26, 2003 whose priority is claimed under 35 USC §119, the disclosure of which is incorporated by reference in its entirety.

### BACKGROUND OF THE INVENTION

1. Field of the Invention

The present invention relates to a semiconductor memory device and a production method therefor. More specifically, the invention relates to a semiconductor memory device which includes a memory cell block having a lower resistance source line formed by a self-alignment process, and to a production method for the semiconductor memory device.

2. Description of the Related Art

In recent years, there has been an increasing demand for portable electronic apparatuses such as mobile phone, portable information terminal, IC card, memory card, portable computer, portable game machine, digital camera, portable motion picture player, portable music player, electronic dictionary and watch. capable of handling a great amount of data including sound data and motion picture data. Therefore, semiconductor devices such as flash memories provided in such mobile phones and the like are increasingly required to have a higher integration density. For the higher integration density, the dimensions of gate electrodes and source/drain regions of memory cells are reduced. However, this results in increases in gate resistances and source/drain resistances, which are disadvantageous for increasing an operating speed. In order to reduce the gate resistances and the source/drain resistances, metal silicide layers are formed in gate electrode formation regions and source/drain formation regions.

One method for microminiaturization of the memory cells is to use a self-alignment technique in which, after formation of control gates and floating gates serving as word lines of the memory cells, portions of isolation oxide films present in source line formation regions are etched away by using the control gates as a mask, and source lines are formed alongside the word lines by ion implantation.

A conventional production method for a semiconductor device including a memory cell block with a source line formed by the self-alignment process will briefly be described with reference to FIG. 14 and FIGS. 15A to 19C. The memory cell block of the conventional semiconductor device is shown in FIG. 14. FIGS. 15A to 19A, 15B to 19B and 15C to 19C are sectional process diagrams taken along lines A-A′, B-B′ and C-C′, respectively, in FIG. 14.

A first electrically conductive film such as of polysilicon (for floating gate electrodes 104 of the memory cells) is formed on a p-type semiconductor substrate 101 having insulative device isolation films 102 with the intervention of a first insulation film (for tunnel insulation films 103). After a second electrically conductive film of polysilicon (for control gates 106 of the memory cells) is formed over the resulting substrate with the intervention of a thin ONO film (for interlayer laminate insulation films 105 of the memory cells), the second electrically conductive film, the ONO film, the first electrically conductive film and the first insulation film are successively patterned by selective etching to form the control gates 106, the interlayer laminate insulation films 105, the floating gates 104 and the tunnel insulation films 103 which each extend perpendicularly to the insulative device isolation films 102 as shown in FIGS. 15A to 15C.

Then, as shown in FIGS. 16A to 16C, a photoresist 107 is deposited on the resulting substrate as having openings in source line formation regions (along the line B-B′), and portions of the insulative device isolation films 102 present on the source line formation regions are etched away in a self-aligned manner by using the photoresist 107 and the control gates 106 as a mask.

Subsequently, as shown in FIGS. 17A to 17C, an N+ impurity (e.g., arsenic ions) is implanted into the semiconductor substrate 101 by using the control gates 106 of the memory cells as a mask. Thus, source regions 108 and drain regions 109 of memory cells and source diffusion layer interconnections (N+ diffusion layers) are formed.

In turn, as shown in FIGS. 18A to 18C, side wall films 110 are formed on side walls of the floating gates 104 and the control gates 106. Then, salicidation is performed on surfaces of the control gates 106, surfaces of the source regions 108 and the drain regions 109 and surfaces of the source diffusion layer interconnections to form metal silicide layers 111. After an interlayer insulation film 112 is formed over the resulting substrate by a CVD method or the like, contact holes are formed in the interlayer insulation film 112. Then, electrically conductive films 113 are respectively formed in the contact holes, and predetermined electrodes 114 are connected to the electrically conductive films. Thus, the semiconductor device is provided, as shown in FIGS. 19A to 19C, which includes the memory cell block whose source lines are formed by the self-alignment process.

In the semiconductor device including the memory cell block whose source lines are formed by the self-alignment process, the source lines extend perpendicularly to the device isolation films. In the source lines, the source diffusion layer interconnections or the metal silicide layers 111 on the surfaces of the source diffusion layer interconnections disadvantageously have a higher resistance.

More specifically, as shown in plan in FIG. 14, the source lines SL are each constituted by a source diffusion layer SL including source regions S (108) arranged generally parallel to a word line G and source diffusion layer interconnections S′ electrically connecting the source regions S (108). As shown in section in FIG. 19B, the portions of the insulative device isolation films 102 present between the source regions 108 (S) are removed to expose trenches TR, and the source diffusion layer SL is present in an undulated surface portion of the substrate and has a metal silicide layer provided in the surface thereof.

Where shallow trench isolation is employed for the device isolation, the trenches formed in the substrate by etching away the portions of the insulative device isolation films present on the source line formation regions with the use of the gate electrodes as the mask each have steeply inclined side walls. Therefore, the impurity ions are not sufficiently implanted into vertical portions of the side walls, making it difficult to allow the source diffusion layer interconnections to have a lower resistance. Further, the presence of the steep trenches in the source line formation regions results in poorer step coverage with a high melting point metal when the metal silicide layers are formed. Therefore, the poorly covered portions are insufficiently silicided and, hence, do not have a desired resistance. Further, when the portions of the insulative device isolation films on the source line formation regions are removed, the interlayer laminate insulation film (ONO film) 105 and the tunnel insulation film 103 are liable to be partly removed, because these films 105, 103 are partly exposed as shown in FIG. 16A. This leads to variations in coupling capacitance, resulting in variations in the characteristics of the memory cells.

Thus, the source lines each have an increased resistance because of the unstable and discontinuous structure of the source diffusion layers or the metal silicide layers formed in the surfaces of the source diffusion layers. The increased resistance may result in malfunction of the memory cells, and hamper the microminiaturization of the memory cells. Hence, there is a demand for a cell structure which ensures formation of lower resistance source lines.

One method for the formation of the lower resistance source lines is to form trenches having side walls inclined at an angle greater than an ion implantation angle to reduce the resistance of the source diffusion layers as disclosed in Japanese Unexamined Patent Publication No. 2000-36546. With this arrangement, impurity ions can be implanted into the inclined side walls of the trenches for formation of lower resistance source diffusion layer interconnections.

In the aforesaid method, the side walls of the trenches are inclined. Therefore, the depth of the trenches is limited, making the microminiaturization of the semiconductor device difficult.

Where a non-selective material is used for the formation of the side wall insulation films on the side walls of the control gates, the side wall insulation films are liable to be removed when the portions of the insulative device isolation films present in the source line formation regions are removed. If the salicide process is performed in this state, the control gates and the floating gates are shorted by the resulting silicide films, making the memory cells inoperative.

Further, where the portions of the silicon substrate in the source line formation regions and the insulative device isolation films are isotropically etched in a self-aligned manner at etching rates for the same selectivity to provide a planar structure with no step in the source line formation regions of the substrate, for example, two photolithography steps are required for the source side and drain side of the control gates. Therefore, it is difficult to control the line width of the control gates, resulting in variations in the characteristics of the memory cells and reduction of the yield of the semiconductor memory device.

### SUMMARY OF THE INVENTION

In view of the foregoing, the present invention provides a semiconductor device having a structure which permits the microminiaturization of the device and the higher speed operation of the device by provision of lower resistance source lines, and a production method for the semiconductor device.

According to one aspect of the present invention, there is positioned a semiconductor memory device which comprises: a semiconductor substrate; a plurality of memory cells arranged in a matrix having columns and rows on the semiconductor substrate and each including a source, a drain and a control gate; a plurality of insulative device isolation layers positioned in a surface portion of the substrate as extending in a column direction for isolating the memory cells arranged in each row of the matrix; a plurality of word lines positioned on the substrate as extending in a row direction and each constituted by the control gates of the memory cells of the each row which are connected in series; the source and the drain of each of the memory cells of the each row being positioned in the surface of the substrate on opposite sides of a corresponding one of the word lines between an adjacent pair of insulative device isolation layers; and a common source line positioned on the substrate between an adjacent pair of word lines with the intervention of side wall films positioned on side walls of the word lines as extending across the insulative device isolation layers and connecting the sources of the memory cells of the each row in series.

According to another aspect of the present invention, there is provided a semiconductor memory device production method for producing a plurality of memory cells arranged in a matrix having columns and rows on a semiconductor substrate and each including a source diffusion layer, a drain diffusion layer, a floating gate and a control gate, and a plurality of common source lines each serially connecting source diffusion layers of memory cells arranged in each row of the matrix, the method comprising the steps of: forming a plurality of insulative device isolation layers each extending in a column direction in a surface portion of a semiconductor substrate; forming a first insulation film at least on the semiconductor substrate; forming a first electrically conductive film on the first insulation film; dividing the first electrically conductive film along the insulative device isolation layers into a plurality of first electrically conductive film portions each extending in the column direction; forming a second insulation film as an interlayer insulation film over the first electrically conductive film portions; forming a second electrically conductive film over the interlayer insulation film; simultaneously patterning the second electrically conductive film, the interlayer insulation film, the first electrically conductive film portions and the first insulation film to form a plurality of gate lines elongated in a row direction and each including floating gates and control gates of memory cells arranged in each row of the matrix; forming drain diffusion layers and source diffusion layers of the respective memory cells in the semiconductor substrate on opposite sides of the gate lines by using the gate lines as a mask; forming third insulation films as side wall insulation films on side walls of the gate lines, the third insulation films each having a thickness such as not to completely cover the source diffusion layers and the drain diffusion layers; forming a third electrically conductive film over the resulting substrate; and selectively removing the third electrically conductive film to leave portions of the third electrically conductive film which each serially connect the source diffusion layers of the memory cells of the each row and each have a smaller height than the side wall films. With this production method, the aforesaid semiconductor memory device can be provided.

### BRIEF DESCRIPTION OF THE DRAWINGS

FIG. 1 is a plan view illustrating the construction of a semiconductor device according to a first embodiment of the present invention;

FIG. 2 is an equivalent circuit diagram illustrating the construction of the semiconductor device according to the first embodiment;

FIGS. 3A to 11A and FIGS. 3B to 11B are sectional views taken along lines A-A′ and B-B′, respectively, in FIG. 1 for explaining a semiconductor memory device production method according to a second embodiment of the present invention;

FIGS. 12A and 12B are sectional views illustrating the construction of a semiconductor memory device according to a fourth embodiment of the present invention;

FIGS. 13A and 13B are sectional views illustrating the construction of a semiconductor memory device according to a fifth embodiment of the present invention;

FIG. 14 is a plan view illustrating the construction of a conventional semiconductor memory device;

FIGS. 15A to 19A, FIGS. 15B to 19B and FIGS. 15C to 19C are sectional views taken along lines A-A′, B-B′ and C-C′, respectively, in FIG. 14 for explaining a conventional semiconductor memory device production method;

FIG. 20 is a schematic configuration diagram of a portable electronic apparatus (sixth embodiment) incorporating therein the semiconductor memory device according to the present invention.

In the inventive semiconductor memory device, the common source lines each serially connecting the sources of the memory cells of the each row are disposed on the substrate between the adjacent word lines with the intervention of the side wall insulation films as extending across the insulative device isolation layers. Therefore, the common source lines can be formed on a relatively flat surface as compared with the conventional method in which the insulative device isolation layers are partly removed and the common source lines are formed in the resulting recesses. Thus, the formation of the common source lines can be achieved without limitation by the angle of the side walls of device isolation trenches. As a result, the semiconductor device can be produced which has stable and lower resistance common source lines. Since the inventive semiconductor device includes the lower resistance common source lines, both the microminiaturization of the device and the higher speed operation of the device can be achieved. In addition, the semiconductor device has stable characteristics with little inter-element or inter-device variations.

The inventive semiconductor memory device production method includes the steps of forming the third electrically conductive film over the resulting substrate, and selectively removing the third electrically conductive film to leave portions of the third electrically conductive film which each serially connect the source diffusion layers of the memory cells of the each row and each have a smaller height than the side wall films. Therefore, the common source lines can be formed on a relatively flat surface as compared with the conventional method in which the insulative device isolation layers are partly removed and the common source lines are formed in the resulting recesses to serially connect the source diffusion layers. Thus, the common source lines can be formed on the relatively flat surface of the substrate formed with the device isolation layers without limitation by the angle of the side walls of the device isolation trenches. As a result, the semiconductor device can be produced which has stable and lower resistance common source lines. Since the semiconductor device produced by the inventive production method includes the stable and lower resistance common source lines, both the microminiaturization of the device and the higher speed operation of the device can be achieved. In addition, the semiconductor device has stable characteristics with little inter-element or inter-device variations.

According to the inventive semiconductor memory device production method, there is no need to remove portions of the insulative device isolation layers present in source line formation regions for the formation of the common source lines. Therefore, the short circuits of the control gates and the floating gates of the semiconductor memory device can be prevented without a possibility that the side wall insulation films are removed from the side walls of the memory cells in the production process.

According to the inventive semiconductor memory device production method, the step of planarizing surface portions of the substrate in the source line formation regions can be eliminated. Thus, the variations in the characteristics of the memory cells attributable to this step can be eliminated, thereby improving the yield of the semiconductor memory device.

### DETAILED DESCRIPTION OF THE INVENTION

A semiconductor memory device according to the present invention includes: a semiconductor substrate; a plurality of memory cells arranged in a matrix having columns and rows on the semiconductor substrate and each including a source, a drain and a control gate; a plurality of insulative device isolation layers positioned in a surface portion of the substrate as extending in a column direction for isolating the memory cells arranged in each row of the matrix; a plurality of word lines positioned on the substrate as extending in a row direction and each constituted by the control gates of the memory cells of the each row which are connected in series; the source and the drain of each of the memory cells of the each row being positioned in the surface of the substrate on opposite sides of a corresponding one of the word lines between an adjacent pair of insulative device isolation layers; and a common source line positioned on the substrate between an adjacent pair of word lines with the intervention of side wall films positioned on side walls of the word lines as extending across the insulative device isolation layers and connecting the sources of the memory cells of the each row in series.

The common source line of the semiconductor device is positioned on the substrate between the adjacent pair of word lines with the intervention of the side wall films positioned on the side walls of the word lines as extending across the insulative device isolation layers and connecting the sources of the memory cells of the each row in series.

A preferred example of the substrate is a monocrystalline silicon substrate, but not limited thereto. Another example of the substrate is an SOI (silicon-on-insulator) substrate. The insulative device isolation layers are formed of silicon oxide. The material for the insulative device isolation layers is not particularly limited, as long as the material is electrically insulative and withstands an oxidation process (e.g., silicon nitride (SiN)). The word lines are preferably composed of polycrystalline silicon. The material for the word lines is not particularly limited, but amorphous silicon and NiSi (metal gate materials) may be used.

The side wall films herein mean insulation films positioned on the side walls of the respective word lines positioned on the substrate for isolating the word lines from the common source line positioned between the word lines connected to the sources. The side wall insulation films may be composed of silicon oxide.

The common source line is formed on the substrate as extending across the insulative device isolation films. Thus, the common source line is formed on a relatively flat surface as compared with the prior art in which the insulative device isolation layers are partly removed and the common source line is formed in the resulting recesses. In addition, a source line material is deposited in the recess defined between the word lines in the present invention, thereby eliminating or alleviating the disadvantages of the prior art attributable to the formation of the metal silicide layers in the undulated surface portions of the substrate.

The memory cells each further include a floating gate of polycrystalline silicon. The floating gate may be at least partly located on a channel region defined between the source and the drain of the memory cell with the intervention of an insulation film, and located below the control gate (word line) with the intervention of an interlayer insulation film. The present invention is applicable to a semiconductor memory device with or without a floating gate.

The common source line may be composed of polycrystalline silicon and a metal silicide. The polycrystalline silicon is widely used for an electrically conductive film, and is suitable as an electrically conductive material for deposition and for formation of a metal silicide. The metal silicide is known as a lower resistance material. Therefore, the common source line composed of the metal silicide has a lower resistance. Examples of a metal to be used for formation of a silicide include cobalt and nickel. The metal is not particularly limited, as long as the metal can form a silicide with silicon for reduction of the resistance.

Alternatively, the common source line may be composed of a metal silicide alone. In this case, the step of forming the common source line of polycrystalline silicon can be eliminated, thereby simplifying the production process as compared with the aforesaid case.

An inventive semiconductor memory device production method is a method for producing a plurality of memory cells arranged in a matrix having columns and rows on a semiconductor substrate and each including a source diffusion layer, a drain diffusion layer, a floating gate and a control gate, and a plurality of common source lines each serially connecting source diffusion layers of memory cells arranged in each row of the matrix. The method comprises the steps of: forming a plurality of insulative device isolation layers each extending in a column direction in a surface portion of a semiconductor substrate; forming a first insulation film at least on the semiconductor substrate; forming a first electrically conductive film on the first insulation film; dividing the first electrically conductive film along the insulative device isolation layers into a plurality of first electrically conductive film portions each extending in the column direction; forming a second insulation film as an interlayer insulation film over the first electrically conductive film portions; forming a second electrically conductive film over the interlayer insulation film; simultaneously patterning the second electrically conductive film, the interlayer insulation film, the first electrically conductive film portions and the first insulation film to form a plurality of gate lines elongated in a row direction and each including floating gates and control gates of memory cells arranged in each row of the matrix; forming drain diffusion layers and source diffusion layers of the respective memory cells in the semiconductor substrate on opposite sides of the gate lines by using the gate lines as a mask; forming third insulation films as side wall insulation films on side walls of the gate lines, the third insulation films each having a thickness such as not to completely cover the source diffusion layers and the drain diffusion layers; and forming third electrically conductive films between the gate lines, the third electrically conductive films each serially connecting the source diffusion layers of the memory cells of the each row and having a smaller height than the side wall films.

In this production method, the third electrically conductive films each having a smaller height than the side wall insulation films and connecting the source diffusion layers of the each row are formed between the gate lines. Therefore, the production method has a reduced number of process steps as compared with the production method in which the third electrically conductive film is formed over the semiconductor substrate and selectively removed.

The production method may further comprise the step of partly or entirely siliciding the third electrically conductive films positioned between the gate lines or partly siliciding the drain diffusion layers.

Thus, the silicidation of the third electrically conductive films is performed simultaneously with the silicidation of the control gates and the drain diffusion layers which is commonly performed in conventional production methods. Therefore, the formation of the very low resistance common source lines can be achieved by adding the step of forming the third electrically conductive films in the common source line formation regions. Further, the third electrically conductive films, the control gates and the drain diffusion layers are isolated from each other by the side wall insulation films, so that the silicidation can be performed in a self-aligned manner.

It is effective to apply the semiconductor memory device to portable electronic apparatuses such as mobile phone, portable information terminal, IC card, memory card, portable computer, portable game machine, digital camera, portable motion picture player, portable music player, electronic dictionary and watch. The semiconductor memory device of the present invention may be provided as at least a part of a control circuit or a data storing circuit of an electronic device or, as necessary, detachably assembled.

It is possible to increase the operation speed of the portable electronic apparatus and reduce the fabrication cost, so as to provide the inexpensive portable electronic apparatus having high reliability and high performance by using, for the portable electronic apparatus, the semiconductor memory device which has high integration density and achieves a reading operation at a high speed.

### DESCRIPTION OF THE PREFERRED EMBODIMENTS

Embodiments of the present invention will hereinafter be described with reference to the attached drawings.

### First Embodiment

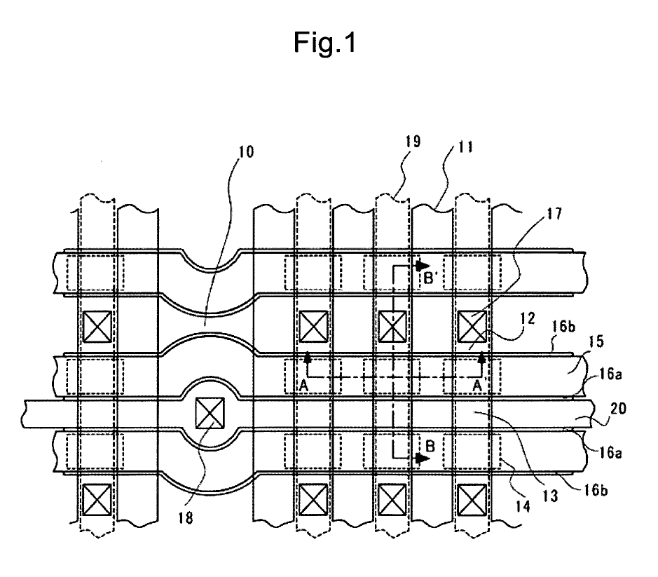

FIG. 1 is a plan view illustrating a semiconductor memory device according to a first embodiment of the present invention. The semiconductor memory device includes a NOR flash memory cell array including memory cells which are arranged in a matrix having columns and rows and each have a floating gate into and from which electrons are injected and released via a tunnel oxide film for a nonvolatile storage operation. A plurality of insulative device isolation films 11 are provided on a semiconductor substrate 10 as extending in a column direction, and a plurality of word lines 15 (control gates) are provided on the semiconductor substrate 10 as extending in a row direction. The memory cells each including a floating gate 14, a control gate 15, a drain diffusion layer 12 and a source diffusion layer 13 are respectively defined at intersections of the word lines 15 and semiconductor active regions defined between the insulative device isolation films 11. Drain contacts 17 provided on a surface of the semiconductor memory device are respectively connected to the drain diffusion layers 12 of the memory cells, and further connected to corresponding bit lines 19 expending parallel to the semiconductor active regions. Common source lines 20 are provided between adjacent pairs of word lines 15 with the intervention of side wall insulation films 16a as extending parallel to the word lines 15, and connected to the source diffusion layers 13 of the memory cells arranged in corresponding rows of the matrix. The common source lines 20 are the feature of the present invention. Source contacts 18 provided on the surface of the semiconductor substrate are respectively connected to the common source lines 20, and further connected to uppermost metal interconnections not shown.

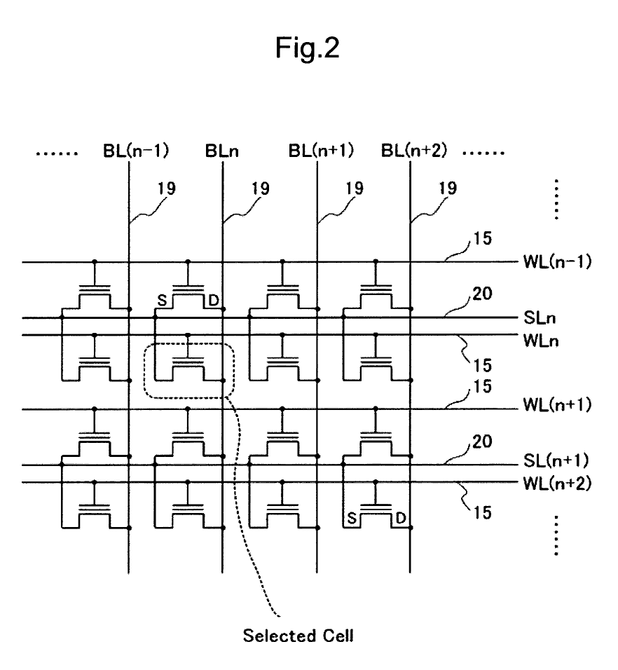

FIG. 2 is an equivalent circuit diagram of the NOR flash memory cell array shown in FIG. 1. The operation of the respective memory cells will be explained with reference to FIG. 2. The writing to a selected memory cell is carried out in the following manner. For example, 10V, 5V and 0V are respectively applied to a word line WLn, a bit line BLn and a common source line SLn connected to the selected cell, and unselected word lines, bit lines and common source lines are kept at 0V. By the application of the voltages, electrons flow from the source diffusion layer 13 to the drain diffusion layer 12 of the selected cell. Some of the electrons are attracted as hot electrons by the potential of the control gate of the selected memory cell, and captured in the floating gate 14 of the selected memory cell for the writing operation.

The erasing of memory cells in a selected memory cell block is carried out in the following manner. For example, −8V and 10V are respectively applied to word lines of the selected memory cells and the substrate 10, whereby electrons captured in floating gates 14 of the memory cells are released to the substrate 10 by an F-N (Fowler-Nordheim) current. The erasing operation is performed for each block of the memory cell array.

The reading of a selected memory cell is carried out in the following manner. For example, 3V, 3V and 0V are respectively applied to a word line WLn, a bit line BLn and a common source line SLn connected to the selected memory cell, and unselected word lines, bit lines and common source lines are kept at 0V. The reading operation is performed on the basis of whether or not a sufficient amount of electrons flow from the source diffusion layer 13 toward the drain diffusion layer 12 of the selected memory cell depending on the applied voltages and the electron storage state of the floating gate 14 of the selected memory cell. More specifically, if electrons are captured in the floating gate 14 of the memory cell, the memory cell is nonconductive. If electrons are not captured in the floating gate 14 of the memory cell, the memory cell is conductive. Thus, the state of the memory cell is determined by detecting a voltage which indicates the nonconductive or conductive state.

### Second Embodiment

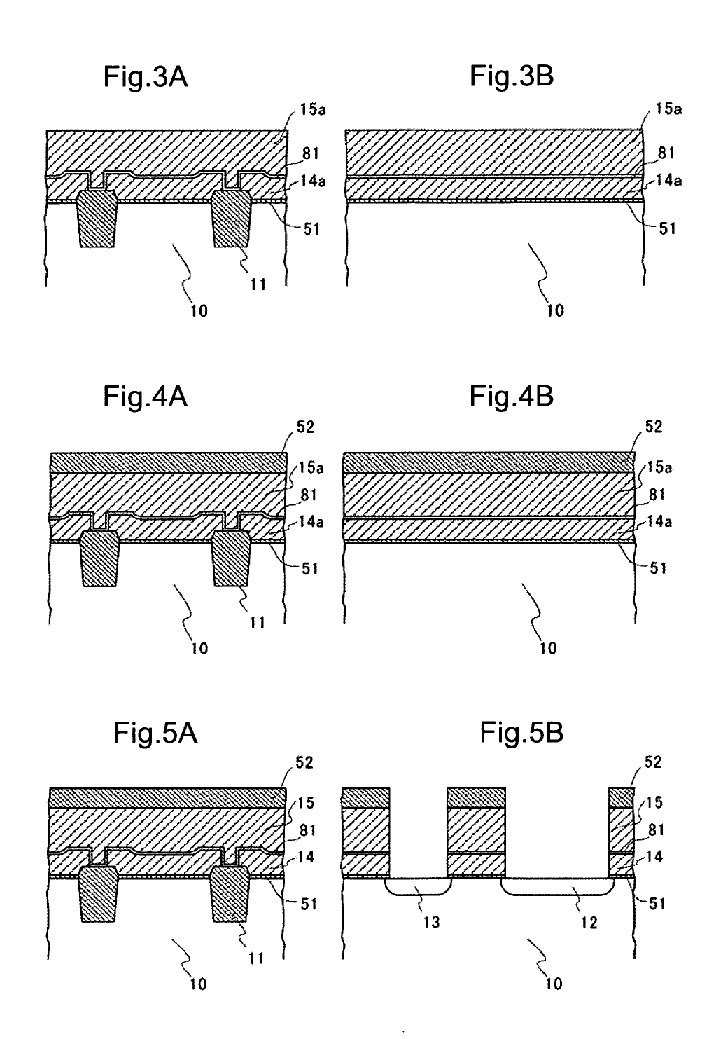

A production method for the aforesaid semiconductor memory device will be explained with referent to FIGS. 3A to 11A and FIGS. 3B to 11B, which are sectional views taken along lines A-A′ and B-B′, respectively, in FIG. 1.

First, a thermal oxide film, for example, having a thickness of about 50 to about 200 and a silicon nitride film, for example, having a thickness of about 1000 to about 2500 are formed on a p-type semiconductor substrate 10. Then, the silicon nitride film and the thermal oxide film are successively patterned by a photolithography process to form a hard mask. Trenches are formed in the p-type semiconductor substrate 10 by etching the p-type semiconductor substrate 10 by anisotropic ion etching with the use of the hard mask. In turn, insulative device isolation films 11 of silicon oxide are formed in the trenches by performing a thermal oxidation process for remedy of crystalline defects, depositing silicon oxide on the resulting substrate, performing a chemical mechanical polishing (CMP) process, and removing the hard mask.

Subsequently, a p-type impurity (e.g., boron ions) for threshold adjustment to be performed after erasing of memory cells by UV irradiation is implanted into the p-type semiconductor substrate 10. After the surface of the resulting substrate is treated with a hydrogen fluoride (HF) solution for removal of a natural oxide film, a tunnel oxide film 51 (first insulation film), for example, having a thickness of about 50 to about 150 is formed, for example, by a thermal oxidation method. Then, polysilicon is deposited to a thickness of about 500 to about 2000 on the resulting substrate by a CVD (chemical vapor deposition) method for formation of a polysilicon film 14a (first electrically conductive film). As required, an n-type impurity (e.g., phosphorus ions) may be introduced into the polysilicon film 14a by ion implantation. Alternatively, a material gas containing the n-type impurity may be used for the formation of the polysilicon film 14a. Thereafter, a hard mask is formed from a material different from the polysilicon film 14a, and the polysilicon film 14a is patterned by a reactive ion etching method so as to be divided into a plurality of polysilicon film portions extending in the row direction perpendicular to the word lines 15. The hard mask for the division of the polysilicon film 14a may be a single layer film or a laminate film. For the division of the polysilicon film 14a, a photoresist mask may be used instead of the hard mask. A material for the mask is not particularly limited, as long as the material has a higher resistance to the reactive ion etching than the polysilicon film.

After the removal of the hard mask, the surface of the resulting substrate is treated with a hydrogen fluoride (HF) solution as required. Then, a silicon oxide film, for example, having a thickness of 20 to 100 is formed on the resulting substrate, for example, by a thermal oxidation method, and a silicon nitride film and a silicon oxide film, for example, each having a thickness of 20 to 100 are successively formed on the resulting substrate, for example, by a CVD method to form an interlayer capacitance film 81 (second insulation film).

Thereafter, polysilicon is deposited to a thickness of about 500 to about 4000 on the resulting substrate, for example, by a CVD method to form a polysilicon film 15a (second electrically conductive film) and, as required, an n-type impurity (e.g., phosphorus ions) is introduced into the polysilicon film 15a by an ion implantation method. Alternatively, a material gas containing the n-type impurity may be used for the formation of the polysilicon film 15a. The substrate provided at this stage is illustrated in section in FIGS. 3A and 3B.

Subsequently, as shown in FIGS. 4A and 4B, silicon oxide is deposited to a thickness of 100 to 4000 on the resulting substrate, for example, by a CVD method to form a silicon oxide film 52. After a photo-mask having a stripe pattern extending perpendicularly to the insulative device isolation films 11 is formed over the resulting substrate, the silicon oxide film 52, the polysilicon film 15a, the interlayer capacitance film 81 and the polysilicon film 14a are sequentially patterned by anisotropic etching with the use of the photo-mask, whereby separate memory cells each including a floating gate 14 and a control gate 15 are simultaneously formed.

In turn, as shown in FIGS. 5A and 5B, an n-type impurity (e.g., arsenic ions) is introduced into exposed surface portions of the semiconductor substrate 10 by an ion implantation method, whereby drain diffusion layers 12 and source diffusion layers 13 are formed on opposite sides of the gates of the memory cells. Thereafter, a thermal oxidation process is performed, as required, for prevention of electron leak from in the floating gates 14. Then, silicon oxide is deposited to a thickness of 100 to 1500 on the resulting substrate, for example, by a CVD method to form a silicon oxide film.

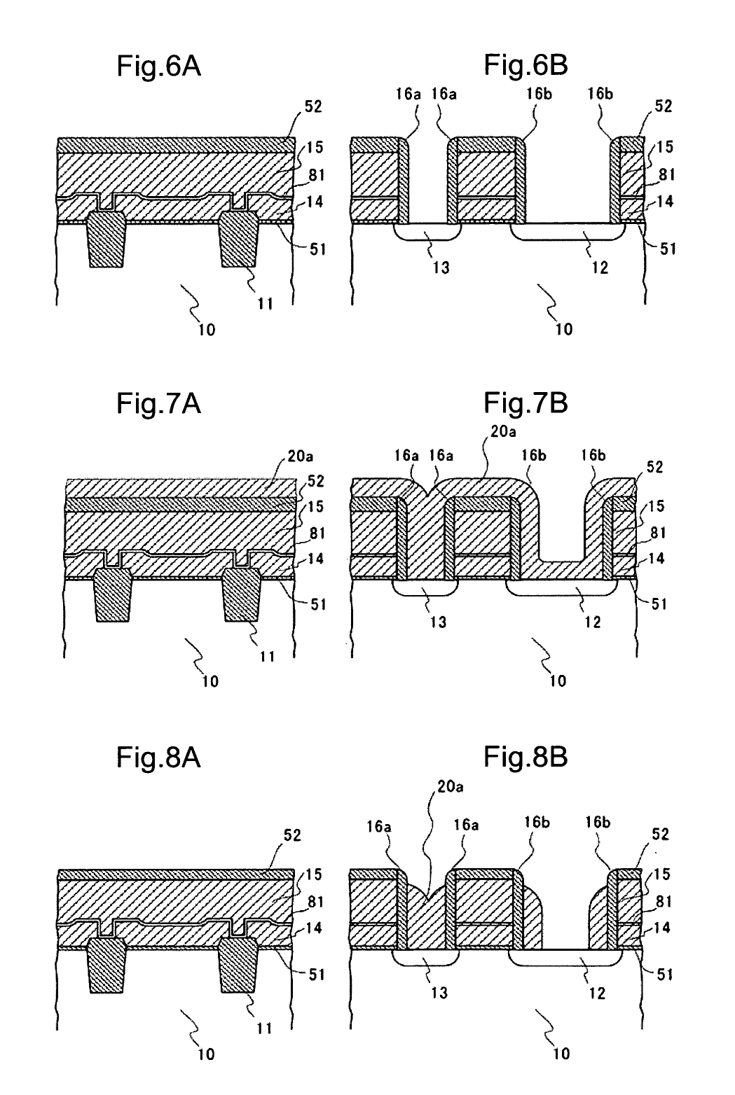

Subsequently, as shown in FIGS. 6A and 6B, the silicon oxide film is anisotropically etched, whereby silicon oxide side wall insulation films 16a, 16b (third insulation films) are formed on side walls of the gates of the memory cells. When the side wall insulation films 16a, 16b are formed, side wall insulation films for formation of an LDD (lightly doped drain) structure of peripheral transistors may also be formed. Further, the widths of the side wall insulation films of the memory cells and the peripheral transistors may be adjusted as required by treating the resulting substrate with an HF solution by using a mask having openings on the memory cells and the peripheral transistors. In the anisotropic etching at this stage, portions of the silicon oxide film present on horizontal surfaces of the resulting substrate need not be completely removed. Further, the anisotropic etching at this stage is not necessarily required. Where the silicon oxide film is partly left on the p-type semiconductor substrate 10 at this stage, it is possible to eliminate a possibility that the p-type semiconductor substrate 10 is inadvertently partly removed when polysilicon is etched and re-deposited for formation of a third electrically conductive film in a later step. The rate of the anisotropic etching of the portions of the silicon oxide film present on surfaces of common source line formation regions parallel to the substrate is reduced by about 10% to about 30% by a micro-loading effect as compared with the etching rate of the silicon oxide film. Therefore, where the film 52 and the third insulation films 16a, 16b are composed of the same material, it is desirable that the thickness of the film 52 is set greater in consideration of the reduction of the etching rate.

As required, the portions of the silicon oxide film on the source diffusion layers 13 are removed, for example, by an anisotropic etching method with the use of a mask having openings on the common source line formation regions. After the resulting substrate is treated with a HF solution for removal of a natural oxide film, as required, polysilicon is deposited to a thickness of 100 to 5000 on the resulting substrate, for example, by a CVD method to form a polysilicon film (third electrically conductive film) as shown in FIGS. 7A and 7B.

Thereafter, as shown in FIGS. 8A and 8B, the polysilicon film is etched back, for example, by a reactive ion etching method, and polysilicon is re-deposited in the resulting recesses for formation of a polysilicon film 20a having a height smaller than the height of the memory cells. Then, as required, an n-type impurity (e.g., phosphorus ions) is introduced into the polysilicon film 20a by an ion implantation method, and the resulting substrate is subjected to an annealing process. Alternatively, a material gas containing the n-type impurity may be used for the deposition and re-deposition of polysilicon for the formation of the polysilicon film 20a.

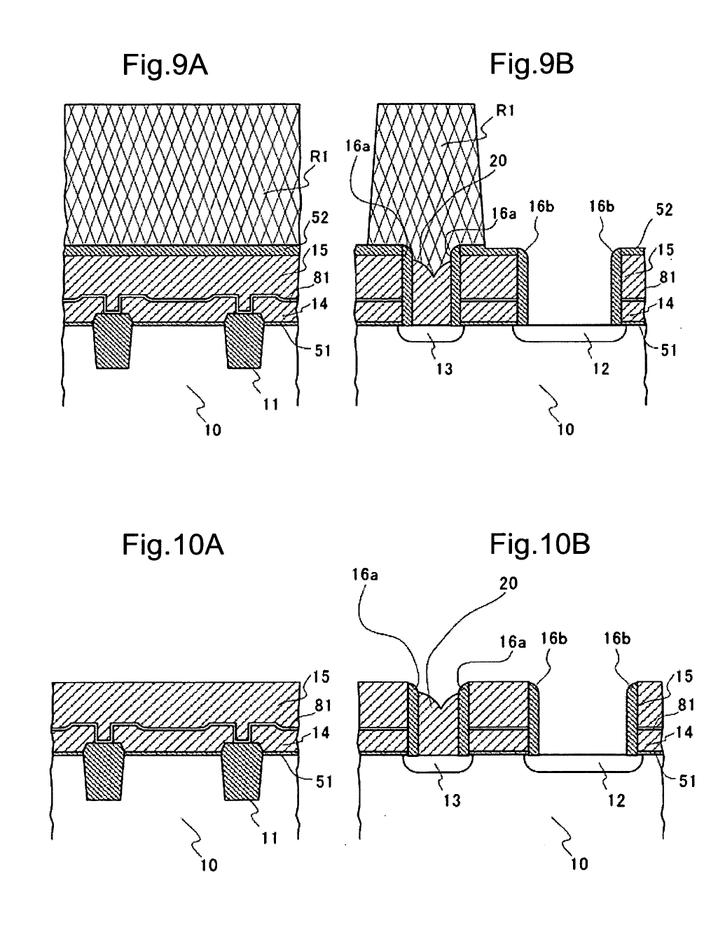

After the common source line formation regions are covered with a resist R1 by a photolithography process as shown in FIGS. 9A and 9B, the polysilicon film 20a is partly removed, for example, by an isotropic etching, and the resist R1 is removed. Thus, separate common source lines 20 are formed. Then, as shown in FIGS. 10A and 10B, portions of the silicon oxide film 52 present on the memory cells are removed, for example, by a reactive ion etching method as required.

Thereafter, an impurity implantation process and a drive-in diffusion process are performed for formation of drain/source diffusion layers of the peripheral transistors. Then, the remaining silicon oxide film is etched away by a reactive ion etching method to expose the drain and source diffusion layers of the memory cells and the peripheral transistors. After argon ions are introduced into the exposed portions of the substrate by ion implantation to make the exposed portions amorphous as required, titanium nitride and cobalt are sequentially deposited on the resulting substrate, for example, by a sputtering method to form a titanium nitride film and a cobalt film. Then, a heat treatment is performed by a RTA (rapid thermal anneal) method, whereby the drain and source diffusion layers and the control gates of the memory cells and the peripheral transistors and the common source lines are at least partly silicided to form metal silicide layers 72. A metal to be used for the silicidation is not limited to cobalt, but another example thereof is nickel. Any metals capable of forming a silicide with silicon for the reduction of the resistance may be used.

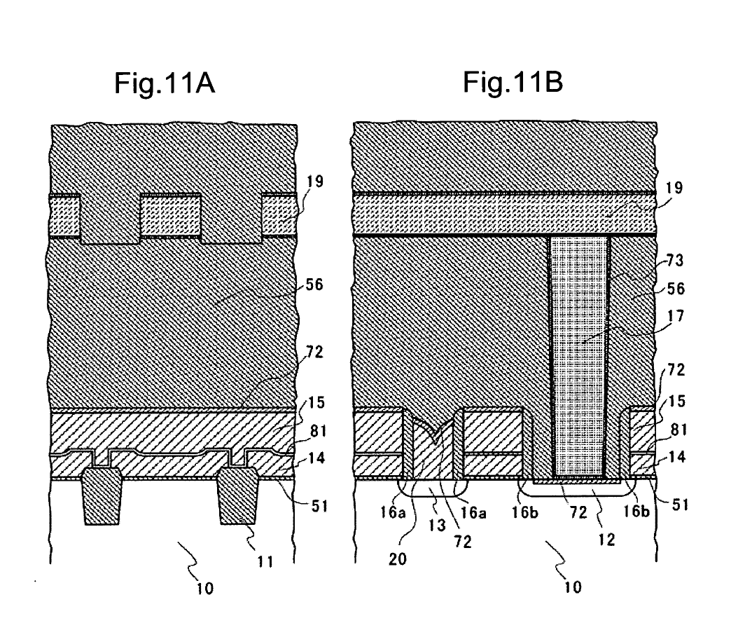

After portions of the titanium nitride film and the cobalt film not silicided are removed, an interlayer film (e.g., BPSG (borophosphosilicate glass film) 56 is formed on the resulting substrate. Then, the resulting substrate is planarized by a reflow process through thermal treatment and further by a chemical mechanical polishing (CMP) process, and contact holes are formed in the interlayer film 56 by a photolithography process and a reactive ion etching process. Thereafter, titanium nitride and titanium are sequentially deposited on interior surfaces of the contact holes by a sputtering method to form adhesive layers 73, and then tungsten is deposited to a thickness of 500 to 5000 in the contact holes by a CVD method and planarized by a chemical mechanical polishing (CMP) process, whereby drain contacts 17, source contacts 18 and the like are formed in the contact holes. Then, interconnections such as bit lines 19 are formed by a known technique. Thus, a semiconductor memory device as shown in FIG. 11 is produced. The inventive semiconductor memory device shown in FIG. 11 has a memory function based on the charge storage states of the respective floating gates 14. The common source lines of the semiconductor memory device each have a reduced resistance.

In this embodiment, the memory cells are formed on the p-type semiconductor substrate, but may be formed in a p-type well surrounded by an n-type well provided in a p-type semiconductor substrate. Alternatively, the memory cells may be formed in a p-type well formed on an insulation film buried in a p-type semiconductor substrate. As long as channel regions of the memory cells are of a p-type semiconductor, it is not important whether or not the channel regions are electrically connected to the semiconductor substrate.

In this embodiment, the thermal oxidation process for the prevention of the electron leak from the floating gates 14 may be performed after the formation of the third insulation films, or may be performed at any stage after the separate memory cells are simultaneously formed.

### Third Embodiment

Although the third electrically conductive film (polysilicon film) 20a is formed by the CVD method in the second embodiment, the formation of the third electrically conductive film is achieved by a silicon epitaxial growth process in this embodiment. A selective epitaxial growth process is performed with the silicon surfaces in the common source line formation regions being partly or entirely exposed and with the drain formation regions being covered, for example, with silicon oxide films.

Thus, the third electrically conductive film is formed only in the common source line formation regions, so that the step of removing unnecessary portions of the third electrically conductive film can be obviated. For reduction of the number of process steps, the production process according to this embodiment is more advantageous than the production process according to the second embodiment in which the third electrically conductive film is formed by the CVD method.

### Fourth Embodiment

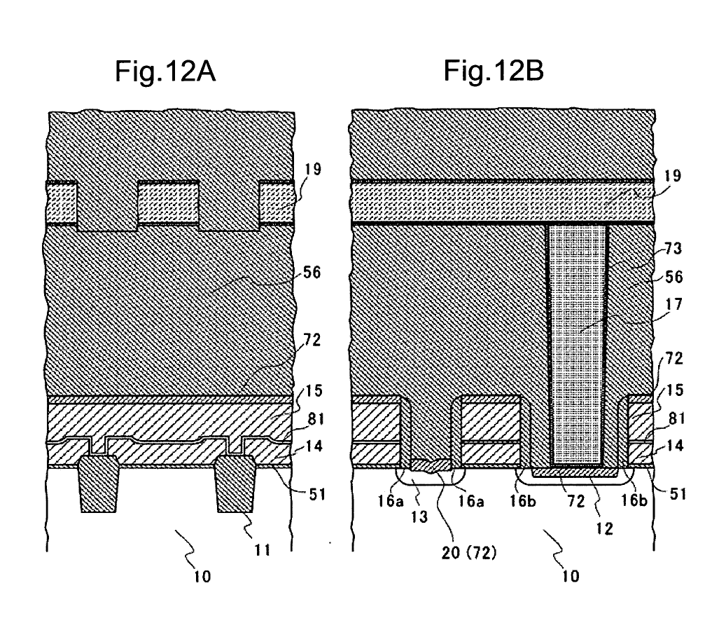

Although the common source lines 20 are partly silicided in the second embodiment, the re-deposition amount of the third electrically conductive film material is increased, and the common source lines 20 are entirely silicided as indicated by a reference numeral 72 in FIGS. 12A and 12B. Alternatively, the common source lines 20 may entirely be silicided, and the source diffusion layers 13 may partly or entirely be silicided. Since the resistance of a metal silicide is one several hundredths to one several thousandths the resistance of polysilicon, the resistances of the common source lines are generally determined by the silicided portions of the common source lines. Portions of the common source lines not silicided do not contribute to the reduction of the resistances of the common source lines.

Where the common source lines 20 are entirely silicided, there is no need to perform the impurity introducing step and the annealing step on the third electrically conductive films. For reduction of the number of process steps, it is more advantageous to select silicidation conditions for entirely siliciding the common source lines 20, if thickness variations of the third electrically conductive films resulting from the increase of the re-deposition amount of the third electrically conductive film are permissible.

In this embodiment, the diffusion layer formation step performed on the word lines after the insulative device isolation films are partly removed in a self-aligned manner in the prior art is eliminated in this embodiment. However, the diffusion layer formation step may be performed to allow the source diffusion layers 13 of the memory cells to have an impurity concentration distribution equivalent to that in the prior art. In this case, however, the number of process steps and the number of the masks are increased. In addition, the aspect ratio of the re-deposited third electrically conductive films to the common source line formation regions is increased. Further, the diffusion layers do not contribute to the reduction of the resistances of the common source lines. Therefore, the diffusion layer formation step is not necessarily more advantageous for the reduction of the resistances of the common source lines and the reduction of the number of process steps than the second embodiment.

### Fifth Embodiment

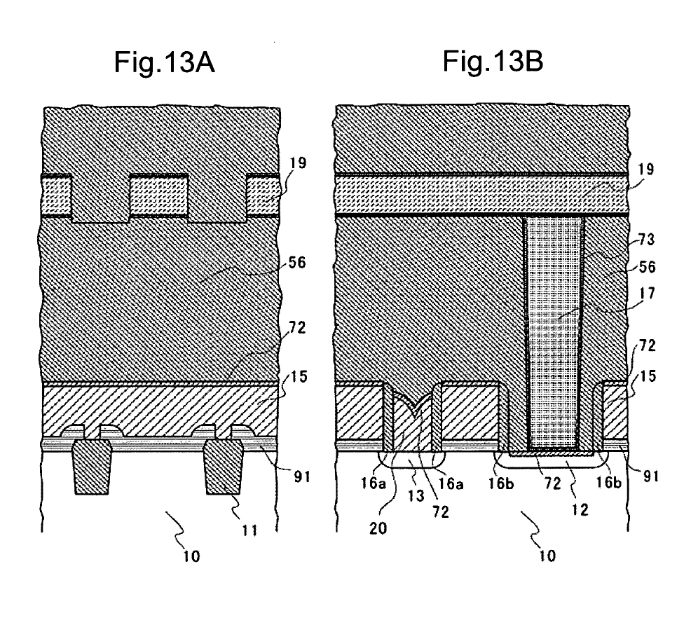

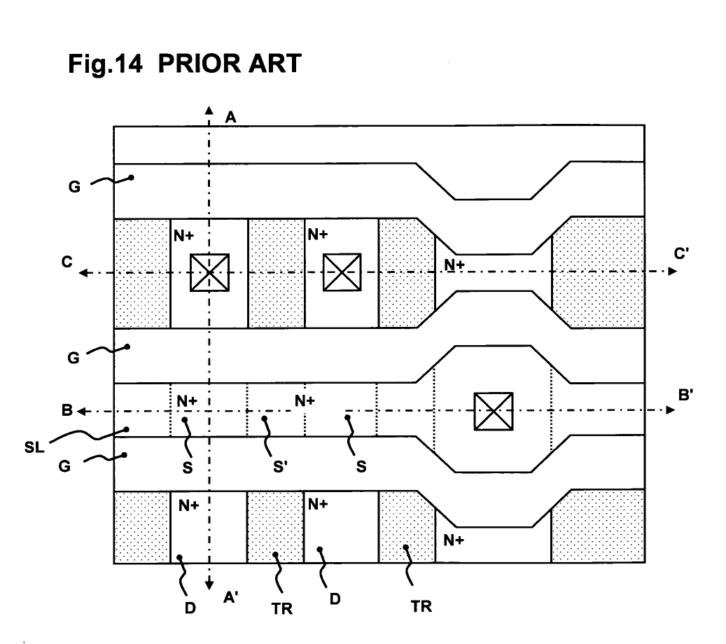

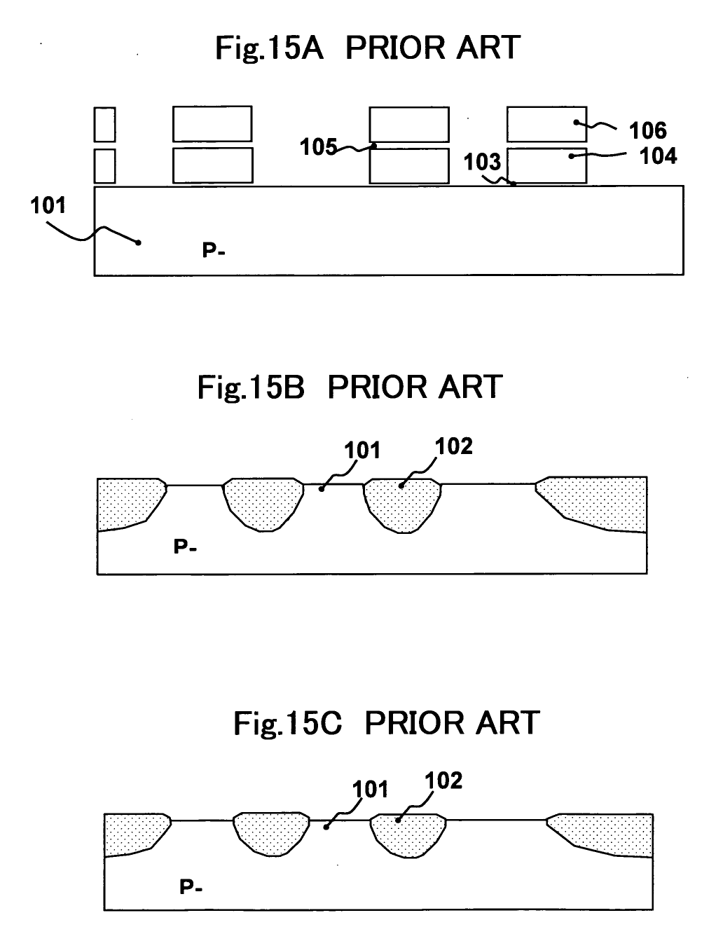

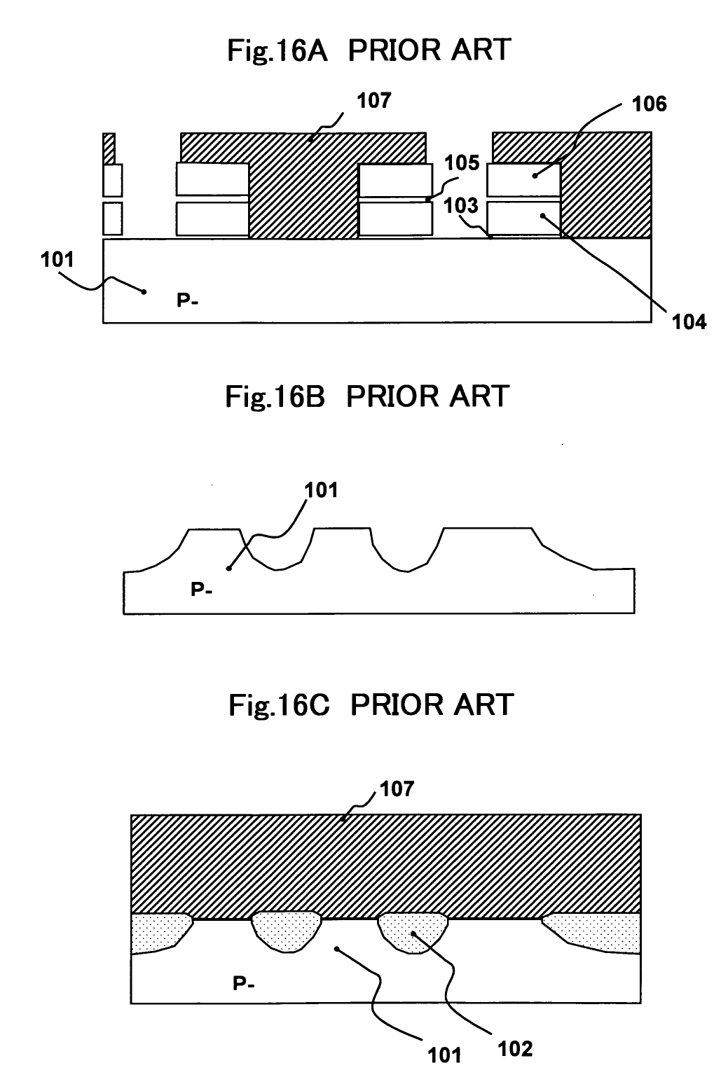

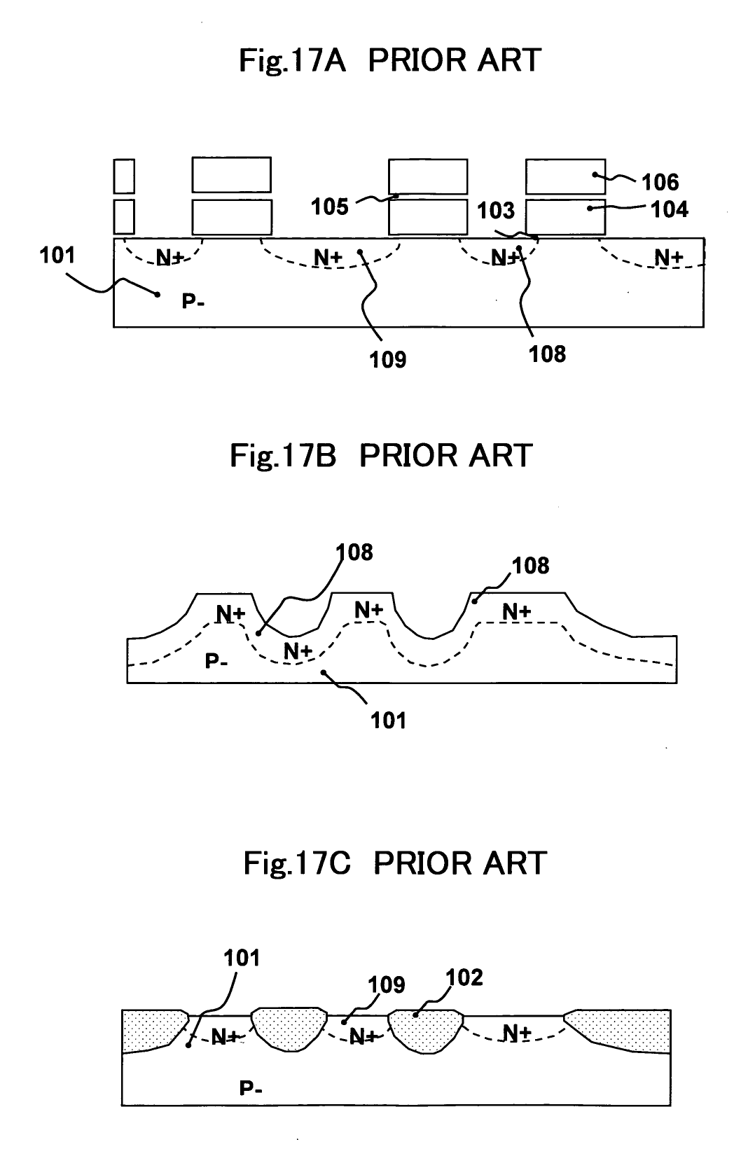

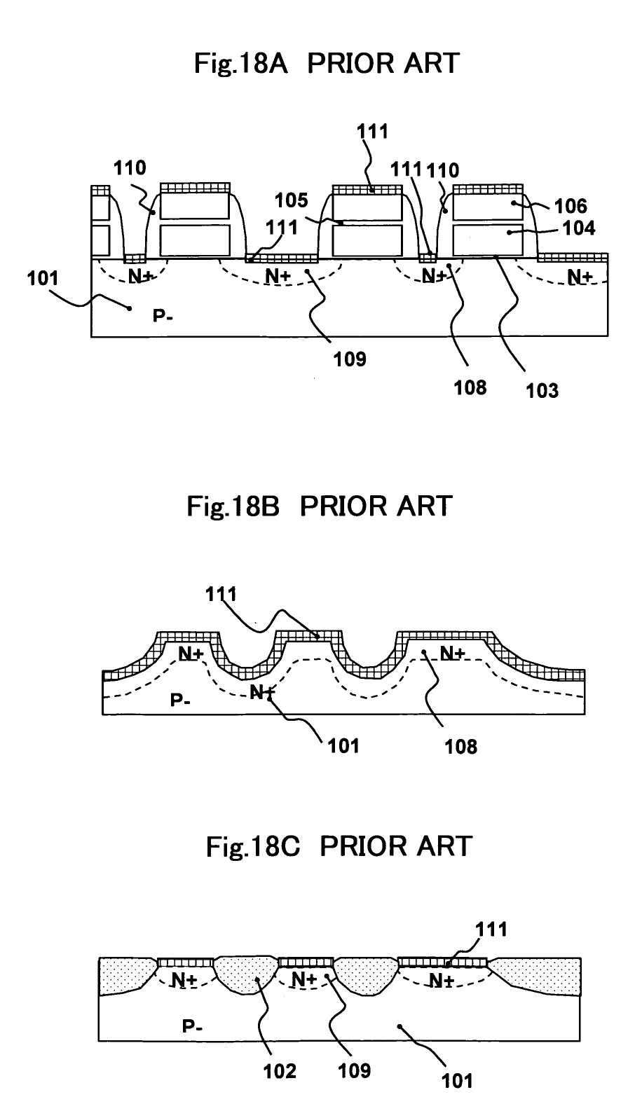

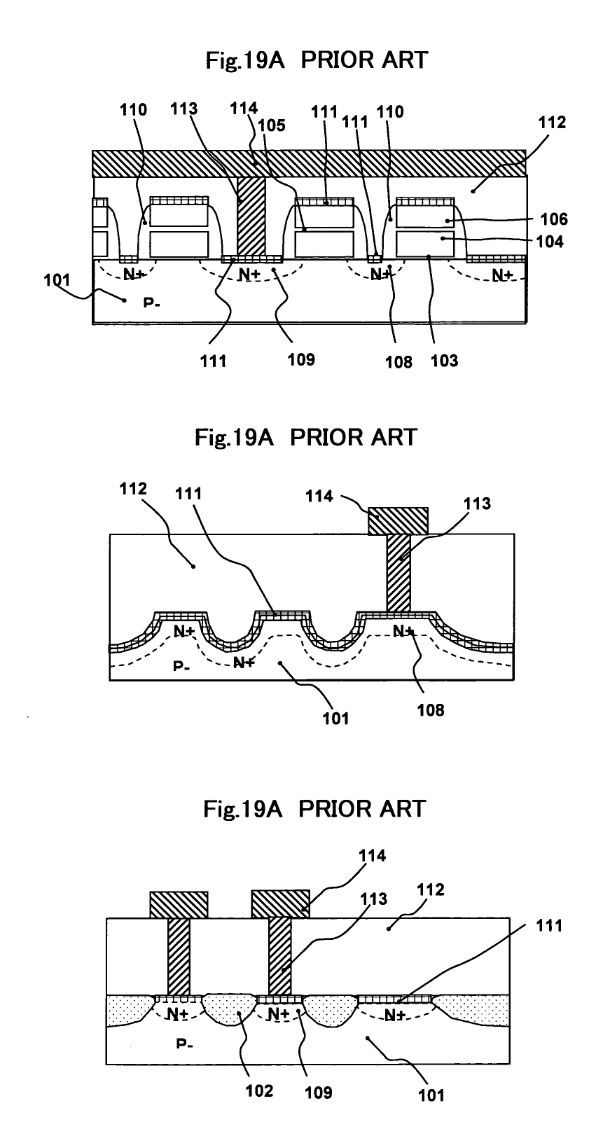

The first to fourth embodiments are directed to NOR flash memory cell arrays as examples of the semiconductor memory device with the common source lines, but the present invention is not limited to these embodiments. FIGS. 13A and 13B are sectional views illustrating a fifth embodiment of the present invention. As shown in FIGS. 13A and 13B, ferroelectric films or ONO laminate films each including a silicon oxide film, a silicon nitride film and a silicon oxide film, for example, may be used for nonvolatile storage layers 91. Alternatively, ferromagnetic films or variable resistance films having different phases may be used for the nonvolatile storage layers 91. The material for the nonvolatile storage layers 91 is not particularly limited, as long as the function of the memory device can be provided by the nonvolatile storage layers 91.

The structures of the memory cells and the interconnections are not limited to those shown in FIGS. 13A and 13B, as long as the common source lines are provided between the adjacent pairs of word lines with the intervention of the side wall insulation films and extend parallel to the word lines across the plurality of insulative device isolation films. For example, additional interconnections may be provided, and the nonvolatile storage layers 91 may be provided in regions different from those shown in FIG. 13B.

Where the diffusion layer formation step performed on the word lines after the insulative device isolation films are partly removed in a self-aligned manner in the prior art is eliminated as described above, the p-type semiconductor substrate 10 is not subjected to the oblique anisotropic etching, but may be subjected to perpendicular isotropic etching when device isolation is carried out by an STI method. In this case, inclined side walls can be eliminated. Therefore, the areas of the cells can be reduced, and the production process can more easily be performed.

According to the present invention, even if the isolation trenches each have steep side walls, the common source lines each having a sufficiently low resistance can be formed irrespective of the angles of the side walls of the trenches as described above. Therefore, the minute memory cell array having a high speed driving capability can be provided according to the present invention.

### Sixth Embodiment

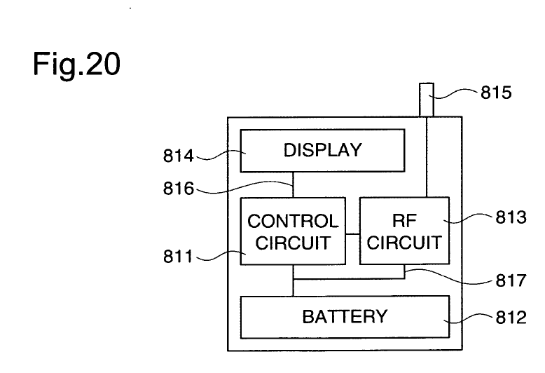

FIG. 20 shows a cellular telephone as a portable electronic apparatus incorporating the above-described semiconductor memory device.

The cellular telephone is mainly constructed by a control circuit 811, a battery 812, an RF (Radio Frequency) circuit 813, a display 814, an antenna 815, a signal line 816 and a power source line 817. The control circuit 811 incorporates therein the above-described semiconductor memory device according to the present invention.

In this manner, it is possible to increase the operation speed of the portable electronic apparatus and reduce the fabrication cost, so as to provide the inexpensive portable electronic apparatus having high reliability and high performance by using, for the portable electronic apparatus, the semiconductor memory device which has high integration density and achieves a reading operation at a high speed.

1. A semiconductor memory device comprising:
a semiconductor substrate;
a plurality of memory cells arranged in a matrix having columns and rows on the semiconductor substrate and each including a source, a drain and a control gate;
a plurality of insulative device isolation layers positioned in a surface portion of the substrate as extending in a column direction for isolating the memory cells arranged in each row of the matrix;
a plurality of word lines positioned on the substrate as extending in a row direction and each constituted by the control gates of the memory cells of the each row which are connected in series;
the source and the drain of each of the memory cells of the each row being positioned in the surface portion of the substrate on opposite sides of a corresponding one of the word lines between an adjacent pair of insulative device isolation layers; and
a common source line positioned on the substrate between an adjacent pair of word lines with the intervention of side wall films positioned on side walls of the word lines as extending across the insulative device isolation layers and connecting the sources of the memory cells of the each row in series.

2. A semiconductor memory device of claim 1, wherein the memory cells each further include a floating
gate of polycrystalline silicon,
wherein the floating gate is at least partly located on a channel region defined between the source and the drain of the memory cell with the intervention of an insulation film, and located below the control gate with the intervention of an interlayer insulation film.

3. A semiconductor memory device of claim 1 wherein the common source line is composed of polycrystalline silicon and a metal silicide.

4. A semiconductor memory device of claim 1 wherein the common source line is composed of a metal silicide.

5. A semiconductor memory device production method for producing a plurality of memory cells arranged in a matrix having columns and rows on a semiconductor substrate and each including a source diffusion layer, a drain diffusion layer, a floating gate and a control gate, and a plurality of common source lines each serially connecting the source diffusion layers of memory cells arranged in each row of the matrix, the method comprising the steps of:
forming a plurality of insulative device isolation layers each extending in a column direction in a surface portion of a semiconductor substrate;
forming a first insulation film at least on the semiconductor substrate;
forming a first electrically conductive film on the first insulation film;
dividing the first electrically conductive film along the insulative device isolation layers into a plurality of first electrically conductive film portions each extending in the column direction;
forming a second insulation film as an interlayer insulation film over the first electrically conductive film portions;
forming a second electrically conductive film over the interlayer insulation film;
simultaneously patterning the second electrically conductive film, the interlayer insulation film, the first electrically conductive film portions and the first insulation film to form a plurality of gate lines elongated in a row direction and each including floating gates and control gates of memory cells arranged in each row of the matrix;
forming drain diffusion layers and source diffusion layers of the respective memory cells in the semiconductor substrate on opposite sides of the gate lines by using the gate lines as a mask;
forming third insulation films as side wall insulation films on side walls of the gate lines, the third insulation films each having a thickness such as not to completely cover the source diffusion layers and the drain diffusion layers;
forming a third electrically conductive film over the resulting substrate; and
selectively removing the third electrically conductive film to leave portions of the third electrically conductive film which
each serially connect the source diffusion layers of the memory cells of the each row and each have a smaller height than the side wall films.

6. A semiconductor memory device production method for producing a plurality of memory cells arranged in a matrix having columns and rows on a semiconductor substrate and each including a source diffusion layer, a drain diffusion layer, a floating gate and a control gate, and a plurality of common source lines each serially connecting the source diffusion layers of memory cells arranged in each row of the matrix, the method comprising the steps of:
forming a plurality of insulative device isolation layers each extending in a column direction in a surface portion of a semiconductor substrate;
forming a first insulation film at least on the semiconductor substrate;
forming a first electrically conductive film on the first insulation film;
dividing the first electrically conductive film along the insulative device isolation layers into a plurality of first electrically conductive film portions each extending in the column direction;
forming a second insulation film as an interlayer insulation film over the first electrically conductive film portions;
forming a second electrically conductive film over the interlayer insulation film;
simultaneously patterning the second electrically conductive film, the interlayer insulation film, the first electrically conductive film portions and the first insulation film to form a plurality of gate lines elongated in a row direction and each including floating gates and control gates of memory cells arranged in each row of the matrix;
forming drain diffusion layers and source diffusion layers of the respective memory cells in the semiconductor substrate on opposite sides of the gate lines by using the gate lines as a mask;
forming third insulation films as side wall insulation films on side walls of the gate lines, the third insulation films each having a thickness such as not to completely cover the source diffusion layers and the drain diffusion layers; and
forming third electrically conductive films between the gate lines, the third electrically conductive films each serially connecting the source diffusion layers of the memory cells of the each row and having a smaller height than the side wall films.

7. A semiconductor memory device production method of claim 5, further comprising the step of partly or entirely siliciding the third electrically conductive films positioned between the gate lines or partly siliciding the drain diffusion layers.

8. A portable electronic apparatus comprising the semiconductor memory device according to claim 1.
